(19) United States
(12) Patent Application Publication
(10) Pub. No.: US 2019/0273133 A1
(43) Pub. Date: Sep. 5, 2019

(54) TRANSISTOR SOURCE/DRAIN AMORPHOUS INTERLAYER ARRANGEMENTS

(71) Applicant: Intel Corporation, Santa Clara, CA (US)

(72) Inventors: Ashish Agrawal, Hillsboro, OR (US); Benjamin Chu-Kung, Portland, OR (US); Seung Hoon Sung, Portland, OR (US); Siddharth Chouksey, Portland, OR (US); Glenn A. Glass, Portland, OR (US); Van H. Le, Portland, OR (US); Anand S. Murthy, Portland, OR (US); Jack T. Kavalieros, Portland, OR (US); Matthew V. Metz, Portland, OR (US); Willy Rachmady, Beaverton, OR (US)

(73) Assignee: Intel Corporation, Santa Clara, CA (US)

(21) Appl. No.: 16/347,110

(22) PCT Filed: Dec. 14, 2016
(86) PCT No.: PCT/US2016/066442

§ 371 Date: May 2, 2019

(51) Int. Cl. H01L 29/08; H01L 29/165; H01L 29/16; H01L 29/36; H01L 29/423; H01L 29/78; H01L 29/06; H01L 29/66; H01L 21/02; H01L 21/324; H01L 29/45; H01L 29/417; H01L 29/10

(52) U.S. Cl. CPC H01L 29/0847; H01L 29/1033; H01L 29/1604; H01L 29/36; H01L 29/42376; H01L 29/785; H01L 29/0673; H01L 29/66795; H01L 21/02532; H01L 21/0262; H01L 21/02576; H01L 21/324; H01L 29/45; H01L 21/02592; H01L 29/41791; H01L 29/165

(57) ABSTRACT

Disclosed herein are transistor amorphous interlayer arrangements, and related methods and devices. For example, in some embodiments, transistor amorphous interlayer arrangement may include a channel material and a transistor source/drain stack. The transistor source/drain stack may include a transistor electrode material configured to be a transistor source/drain contact, i.e. either a source contact or a drain contact of the transistor, and a doped amorphous semiconductor material disposed between the transistor electrode material and the channel material.

### BACKGROUND

During operation of a transistor, current flows between source and drain terminals of the transistor. Therefore, resistance associated with source and drain electrodes (i.e. the contact regions) affects performance of a transistor.

### BRIEF DESCRIPTION OF THE DRAWINGS

Embodiments will be readily understood by the following detailed description in conjunction with the accompanying drawings. To facilitate this description, like reference numerals designate like structural elements. Embodiments are illustrated by way of example, and not by way of limitation, in the figures of the accompanying drawings.

FIG. 1 is a cross-sectional side view of a transistor amorphous interlayer arrangement including a transistor source/drain stack, in accordance with various embodiments.

FIGS. 2 and 3 are cross-sectional side views of example single-gate transistors including a transistor source/drain stack, in accordance with various embodiments.

FIGS. 4A and 4B are perspective and cross-sectional side views, respectively, of an example tri-gate transistor including a transistor source/drain stack, in accordance with various embodiments.

FIGS. 5A and 5B are perspective and cross-sectional side views, respectively, of an example all-around gate transistor including a transistor source/drain stack, in accordance with various embodiments.

FIG. 6 is a flow diagram of an example method of manufacturing a transistor including a source/drain stack, in accordance with various embodiments.

FIGS. 7A and 7B are top views of a wafer and dies that include one or more transistors having transistor source/drain stacks in accordance with any of the embodiments disclosed herein.

FIG. 8 is a cross-sectional side view of an integrated circuit (IC) device that may include one or more transistors having transistor source/drain stacks in accordance with any of the embodiments disclosed herein.

FIG. 9 is a cross-sectional side view of an IC device assembly that may include one or more transistors having transistor source/drain stacks in accordance with any of the embodiments disclosed herein.

FIG. 10 is a block diagram of an example computing device that may include one or more transistor source/drain stacks in accordance with any of the embodiments disclosed herein.

### DETAILED DESCRIPTION

Disclosed herein are transistor amorphous interlayer arrangements, and related methods and devices. For example, in some embodiments, transistor amorphous interlayer arrangement may include one or more semiconductor materials forming a channel of a transistor, the semiconductor material of the channel (i.e., “channel material”) being e.g. germanium, and a transistor source/drain stack. The transistor source/drain stack may include a transistor electrode material configured to be a transistor source/drain contact, i.e. either a source contact or a drain contact of the transistor, and a doped amorphous semiconductor material disposed between the transistor electrode material and the channel material.

The performance of a transistor may depend on the number of factors. For example, one factor is mobility of charge carriers (i.e. electrons for an N-type channel or holes for a P-type channel) in a channel of a transistor. All else equal, a material with a higher carrier mobility enables carriers to move more quickly in response to a given electric field than a material with a lower carrier mobility; thus, high carrier mobilities may be associated with improved performance.

New materials are continuously investigated in an attempt to increase channel mobility. However, some materials, while being promising in terms of their carrier mobility, present challenges when it comes to resistance offered by source/drain contact regions when such materials are used as channel materials. As is well-known, source/drain regions of a transistor are regions where the channel material is highly doped to supply charge carriers for the channel. Activating all, or a majority, of the dopants implanted into the channel material beyond its intrinsic solid solubility limit is sometimes referred to as “super activation.” Super activation is very difficult to achieve with some, otherwise promising, potential channel materials due to defect formation. A height of a Schottky barrier, in this case a potential energy barrier formed at a junction of a source/drain contact electrode metal and a semiconductor material of a channel, is another issue for some channel materials.

Germanium (Ge) is an example of such a material. Due to its higher mobility and lower effective mass, Ge channel is a promising candidate for future, scaled, transistor nodes. However, the external resistance of the source/drain contacts regions due to lower activated doping concentration that can be achieved in Ge, as well as relatively high Schottky barrier height, especially for N-type channels, are dominant performance limiting factors for Ge transistors.

Known solutions to reducing the Schottky barrier height and reducing source/drain contact resistance include using a thin layer of insulator between a source/drain contact electrode and the highly doped crystalline source/drain region. However, using an insulator adds a tunneling barrier in series with the source/drain contacts, which prevents effective reduction of source/drain contact resistivity. In addition, the resistivity is highly sensitive to variations in the insulator thickness, where even sub-nanometer variations in insulator thickness result in non-negligible variations in resistivity, presenting problems with reliably manufacturing transistors with comparable performance characteristics.

The transistor arrangements disclosed herein include a multilayer transistor source/drain stacks having a transistor electrode material configured to be a transistor source/drain contact, i.e. either a source contact or a drain contact of the transistor, and a thin layer of a doped amorphous semiconductor material acting as an interface between the transistor electrode material and a channel material (or, in some embodiments, acting as the channel material itself). In some embodiments, a thin layer of the doped amorphous semiconductor material, referred to in the following as an “amorphous semiconductor interlayer” or simply an “amorphous interlayer,” may directly border a channel material of choice, and may be sandwiched between the channel material and the transistor source/drain contact material.

The use of an amorphous semiconductor interlayer as proposed herein at the interface between the transistor source/drain contact material and the channel may achieve one or more of a number of advantages. An amorphous interlayer may have a super activated doping concentration which, in turn, reduces tunneling distance for the charge carriers and, hence, reduces the external resistance to the transistor, thereby drastically improving transistor performance. In addition, insertion of an amorphous interlayer does not present a tunneling barrier, as was the case with the known solutions that relied on the use of an insulator, because the interlayer proposed herein is a semiconductor layer and, therefore, there is no increase in bandgap due to the presence of this layer. Moreover, contact resistivity is significantly less sensitive to variations in amorphous interlayer thickness than to insulator thickness described above, thereby reducing or even substantially eliminating challenges due to variations in source/drain contact resistivity. Overall, the amorphous interlayer arrangements disclosed herein enable the use of a wider array of transistor channel materials, while achieving desirable source/drain performance, than realizable using conventional approaches.

Tri-gate transistor arrangements with sub-fin dielectric stacks described herein may be implemented in one or more components associated with an integrated circuit (IC) or/and between various such components. In various embodiments, components associated with an IC include, for example, transistors, diodes, power sources, resistors, capacitors, inductors, sensors, transceivers, receivers, antennas, etc. Components associated with an IC may include those that are mounted on IC or those connected to an IC. The IC may be either analog or digital and may be used in a number of applications, such as microprocessors, optoelectronics, logic blocks, audio amplifiers, etc., depending on the components associated with the IC. The IC may be employed as part of a chipset for executing one or more related functions in a computer.

For purposes of explanation, specific numbers, materials and configurations are set forth in order to provide a thorough understanding of the illustrative implementations. However, it will be apparent to one skilled in the art that the present disclosure may be practiced without the specific details or/and that the present disclosure may be practiced with only some of the described aspects. In other instances, well-known features are omitted or simplified in order not to obscure the illustrative implementations.

Further, references are made to the accompanying drawings that form a part hereof, and in which is shown, by way of illustration, embodiments that may be practiced. It is to be understood that other embodiments may be utilized and structural or logical changes may be made without departing from the scope of the present disclosure. Therefore, the following detailed description is not to be taken in a limiting sense.

Various operations may be described as multiple discrete actions or operations in turn, in a manner that is most helpful in understanding the claimed subject matter. However, the order of description should not be construed as to imply that these operations are necessarily order dependent. In particular, these operations may not be performed in the order of presentation. Operations described may be performed in a different order from the described embodiment. Various additional operations may be performed, and/or described operations may be omitted in additional embodiments.

For the purposes of the present disclosure, the phrase “A and/or B” means (A), (B), or (A and B). For the purposes of the present disclosure, the phrase “A, B, and/or C” means (A), (B), (C), (A and B), (A and C), (B and C), or (A, B, and C). The term “between,” when used with reference to measurement ranges, is inclusive of the ends of the measurement ranges.

The description uses the phrases “in an embodiment” or “in embodiments,” which may each refer to one or more of the same or different embodiments. The terms “comprising,” “including,” “having,” and the like, as used with respect to embodiments of the present disclosure, are synonymous. The disclosure may use perspective-based descriptions such as “above,” “below,” “top,” “bottom,” and “side”; such descriptions are used to facilitate the discussion and are not intended to restrict the application of disclosed embodiments. The accompanying drawings are not necessarily drawn to scale. Unless otherwise specified, the use of the ordinal adjectives “first,” “second,” and “third,” etc., to describe a common object, merely indicate that different instances of like objects are being referred to, and are not intended to imply that the objects so described must be in a given sequence, either temporally, spatially, in ranking or in any other manner.

In the following detailed description, various aspects of the illustrative implementations will be described using terms commonly employed by those skilled in the art to convey the substance of their work to others skilled in the art. For example, as used herein, a “high-k dielectric” refers to a material having a higher dielectric constant than silicon oxide. The terms “substantially,” “close,” “approximately,” “near,” and “about,” generally refer to being within +/−20% of a target value based on the context of a particular value as described herein or as known in the art. The terms “oxide,” “carbide,” “nitride,” etc. refer to compounds containing, respectively, oxygen, carbon, nitrogen, etc.

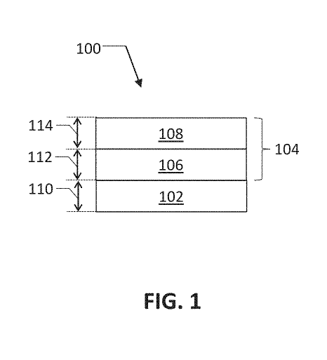

FIG. 1 is a cross-sectional side view of a transistor amorphous interlayer arrangement 100 including a channel material 102 and a transistor source/drain (S/D) stack 104, together forming an active region of a transistor, in accordance with various embodiments. The transistor S/D stack 104 may include a S/D electrode material 108, and a doped amorphous semiconductor material 106 disposed between the S/D electrode material 108 and the channel material 102.

The channel material 102 may be composed of semiconductor material systems including, for example, N-type or P-type materials systems.

In some embodiments, the channel material 102 may be formed of a monocrystalline semiconductor. In some embodiments, the channel material 102 may be formed of a compound semiconductor with a first sub-lattice of at least one element from group III of the periodic table (e.g., Al, Ga, In), and a second sub-lattice of at least one element of group V of the periodic table (e.g., P, As, Sb). In some embodiments, the channel material 102 may be a binary, ternary, or quaternary III-V compound semiconductor that is an alloy of two, three, or even four elements from groups III and V of the periodic table, including boron, aluminum, indium, gallium, nitrogen, arsenic, phosphorus, antimony, and bismuth.

For exemplary P-type transistor embodiments, the channel material 102 may advantageously be a group IV material having a high hole mobility, such as, but not limited to Ge or a Ge-rich SiGe alloy. For some exemplary embodiments, the channel material 102 has a Ge content between 0.6 and 0.9, and advantageously is at least 0.7.

For exemplary N-type transistor embodiments, the channel material 102 may advantageously be a III-V material having a high electron mobility, such as, but not limited to InGaAs, InP, InSb, and InAs. For some such embodiments, the channel material 102 may be a ternary III-V alloy, such as InGaAs or GaAsSb. For some InₓGa₁₋ₓAs fin embodiments, In content (x) is between 0.6 and 0.9, and advantageously is at least 0.7 (e.g., In_{0.7},Ga_{0.3}As).

In some embodiments, the channel material 102 may include a high mobility oxide semiconductor material, such as tin oxide, antimony oxide, indium oxide, indium tin oxide, titanium oxide, zinc oxide, indium zinc oxide, gallium oxide, titanium oxynitride, ruthenium oxide, or tungsten oxide.

The channel material 102 may have a thickness 110. In some embodiments, the thickness 110 may be between 5 and 30 nanometers.

In some embodiments, the channel material 102 is an intrinsic III-V or IV semiconductor material or alloy and not intentionally doped with any electrically active impurity. In alternate embodiments, one or more a nominal impurity dopant level may be present within the channel material 102, for example to set a threshold voltage Vt, or to provide HALO pocket implants, etc. In such impurity-doped embodiments however, impurity dopant level within the channel material 102 may be relatively low, for example below 10¹⁵ cm⁻³, and advantageously below 10¹³ cm⁻³.

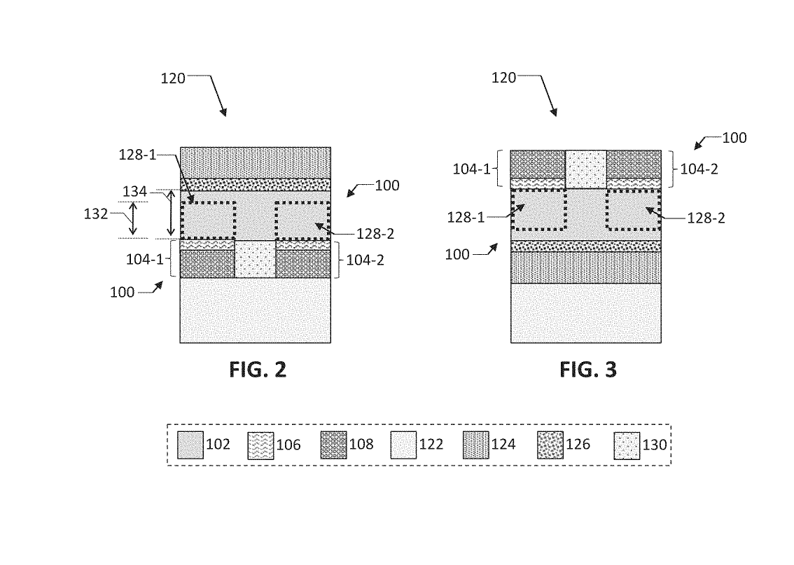

In other embodiments, the channel material 102 that interfaces the doped amorphous semiconductor material 106 may include a region (not specifically shown in FIG. 1) comprising one or more highly doped crystalline semiconductor materials, formed using either an implantation/diffusion process or a deposition process. In the former process, dopants such as boron, aluminum, antimony, phosphorous, or arsenic may be ion-implanted into the channel material 102 to form the highly doped regions. An annealing process that activates the dopants and causes them to diffuse farther into the channel material 102 may follow the ion implantation process. In the latter process, an epitaxial deposition process may provide material that is used to fabricate the highly doped regions. In some implementations, the highly doped regions may be fabricated using a silicon alloy such as silicon germanium or silicon carbide. In some embodiments, the epitaxially deposited silicon alloy may be doped in situ with dopants such as boron, arsenic, or phosphorous. In some embodiments, the highly doped regions may be formed using one or more alternate semiconductor materials such as germanium or a group III-V material or alloy. In further embodiments, one or more layers of metal and/or metal alloys may be used to form the highly doped regions. In some embodiments, an etch process may be performed before the epitaxial deposition to create recesses in the channel material 102 in which the material for the highly doped regions is deposited. Whether including highly doped regions or undoped, portions of the channel material 102 associated with the source and drain electrodes are referred to herein as S/D regions, e.g. as shown with S/D regions 128-1 and 128-2 for the transistors 120 of FIGS. 2-5.

The doped amorphous semiconductor material 106 may include an amorphous semiconductor material such as, but not limited to, germanium, silicon, or silicon germanium, and may be formed using any known deposition processes for depositing amorphous semiconductors, such as physical vapor deposition (PVD) (e.g., sputtering), atomic layer deposition (ALD), or chemical vapor deposition (CVD). The doped amorphous semiconductor material 106 may be deposited on sidewalls or conformably on any desired structure to a precise thickness, allowing the manufacture of transistors having any desired geometry.

The ability to select an amorphous semiconductor material 106 such that temperatures used in subsequent manufacturing processes would be below the temperature at which the amorphous semiconductor material 106 would re-crystallize represents a particular advantage. For example, the crystallization temperature for silicon germanium and silicon amorphous films is significantly higher than the overall process temperatures used during transistor manufacturing. Therefore, when used as the amorphous semiconductor material 106, these amorphous films will not get re-crystallized after all of the processing.

Besides having suitable crystallization temperature to prevent recrystallization during further manufacturing processes, in general, the doped amorphous semiconductor material 106 may include any amorphous semiconductor material having a conduction band offset (for N-type transistors) or valence band offset (for P-type transistors) with respect to the channel material 102, e.g. germanium, that is less than 25 milli-electron-Volt (meV).

The doped amorphous semiconductor material 106 is intentionally doped with electrically active impurities. Such impurities could include impurity dopant atoms such as, but not limited to phosphorus, arsenic, or antimony as N-type dopants and boron or gallium as P-type dopants. The doped amorphous semiconductor material 106 is intentionally doped with N-type dopants when the transistor in which it is included is an N-type transistor and is doped with P-type dopants when the transistor is a P-type transistor. In some embodiments, impurity dopant level within the doped amorphous semiconductor material 106 is relatively high, for between 1·10²⁰ cm⁻³ and 3·10²⁰ cm⁻³. Because the doped amorphous semiconductor material 106 has super activated dopant concentration, tunneling distance is reduced, thereby reducing the external resistance of the S/D electrodes.

The doped amorphous semiconductor material 106 may have a thickness 112. In some embodiments, the thickness 112 may be between 1 nanometers and 10 nanometers, preferably between 1 nanometers and 5 nanometers. The doped amorphous semiconductor material 106 may be in contact with the channel material 102 and/or in contact with the S/D electrode material 108, and may provide the interface between the channel material 102 and the S/D electrode material 108.

The S/D electrode material 108 may include any suitable electrically conductive material, alloy, or a stack of multiple electrically conductive materials. In some embodiments, the S/D electrode material 108 may include one or more metals or metal alloys, with metals such as e.g. ruthenium, palladium, platinum, cobalt, nickel, hafnium, zirconium, titanium, tantalum, and aluminum. In some embodiments, the S/D electrode material 108 may include one or more electrically conductive alloys oxides or carbides of one or more metals. The S/D electrode material 108 may have a thickness 114. In some embodiments, the thickness 114 may be between 10 nanometers and 1000 nanometers, preferably between 10 nanometers and 100 nanometers.

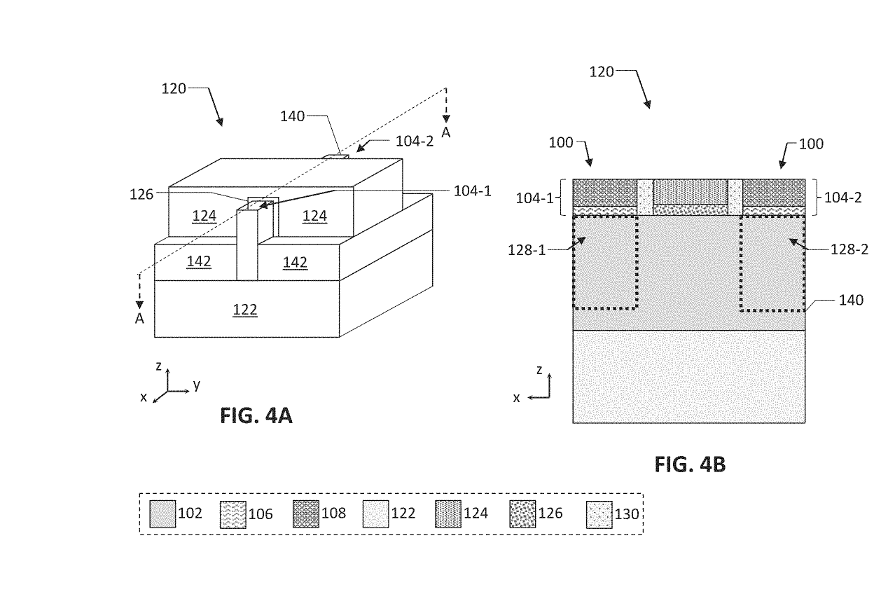

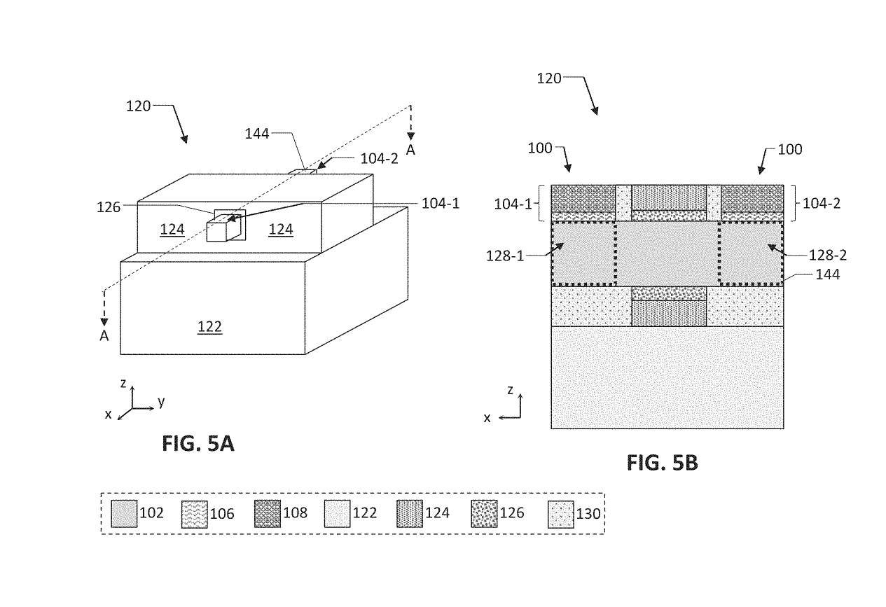

The transistor S/D stack 104 may be included in any suitable transistor structure. For example, FIGS. 2-3 are cross-sectional side views of example single-gate transistors 120 including a transistor S/D stack 104, FIGS. 4A and 4B are perspective and cross-sectional side views, respectively, of an example tri-gate transistor 120 including a transistor source/drain stack 104, FIGS. 5A and 5B are perspective and cross-sectional side views, respectively, of an example all-around gate transistor 120 including a transistor source/drain stack 104, in accordance with various embodiments. The transistors 120 illustrated in FIGS. 2-5 do not represent an exhaustive set of transistor structures in which a transistor S/D stack 104 may be included, but may provide examples of such structures. Although particular arrangements of materials are discussed below with reference to FIGS. 2-5, intermediate materials may be included in the S/D stacks 104 of the transistors 120. Note that FIGS. 2-5 are intended to show relative arrangements of the components therein, and that transistors 120 may include other components that are not illustrated (e.g., gate spacers or various interfacial layers). Any of the components of the transistors 120 discussed below with reference to FIGS. 2-5 may take the form of any of the embodiments of those components discussed above with reference to FIG. 1. Additionally, although various components of the transistors 120 are illustrated in FIGS. 2-5 as being planar rectangles or formed of rectangular solids, this is simply for ease of illustration, and embodiments of these transistors 120 may be curved, rounded, or otherwise irregularly shaped as dictated by the manufacturing processes used to fabricate the transistors 120.

FIG. 2 depicts a transistor 120 including a transistor S/D stack 104 and having a single “top” gate provided by a gate electrode material 124 and a gate dielectric 126. In FIG. 2 and figures illustrating the transistor 120, a transistor stack 104-1 is intended to illustrate a transistor source stack, while a transistor stack 104-2 is intended to illustrate a transistor drain stack, thus individually showing the source and the drain of each transistor 120.

As shown in FIG. 2, each of the transistor source stack 104-1 and the transistor drain stack 104-2 includes the S/D electrode material 108 and the doped amorphous semiconductor material 106 disposed between the S/D electrode material 108 and the channel material 102, as described above with reference to FIG. 1. As also shown in FIG. 2, a dielectric spacer 130 may be provided between the transistor source stack 104-1 and the transistor drain stack 104-2 in order to provide electrical isolation between the source and drain electrodes. The dielectric spacer 130 may be made of a low-k dielectric material (i.e. a dielectric material that has a lower dielectric constant (k) than silicon dioxide which has a dielectric constant of 3.9). Examples of low-k materials that may be used in the dielectric spacer 130 may include, but are not limited to, fluorine-doped silicon dioxide, carbon-doped silicon dioxide, spin-on organic polymeric dielectrics such as e.g. polyimide, polynorbornenes, benzocyclobutene, and polytetrafluoroethylene (PTFE), or spin-on silicon based polymeric dielectric such as e.g. hydrogen silsesquioxane (HSQ) and methylsilsesquioxane (MSQ)). Other examples of low-k materials that may be used in the dielectric spacer 130 include various porous dielectric materials, such as for example porous silicon dioxide or porous carbon-doped silicon dioxide, where large voids or pores are created in a dielectric in order to reduce the overall dielectric constant of the layer, since voids can have a dielectric constant of nearly 1.

Transistor 120 shown in FIG. 2 and the subsequent figures illustrates source and drain regions as regions 128-1 and 128-2, respectively, indicated with dotted lines. In some embodiments, the S/D regions 128-1 and 128-2 are highly doped regions of the crystalline channel material 102. In other embodiments, the S/D regions 128-1 and 128-2 may include undoped channel material 102, i.e. the high doping is optional, because the dopant super activation is provided by the doped amorphous semiconductor material 106, thus advantageously eliminating the need to have highly doped regions in the channel material 102.

In some embodiments, at least some of the channel material 102 may be coplanar with the S/D regions 128-1 and 128-2, as shown in FIG. 2 with some of the channel material 102 disposed between the source region 128-1 and the drain region 128-2. The source region 128-1 and the drain region 128-2 may have a thickness 132, and the channel material 102 may have a thickness 134. In some embodiments, the thickness 132 may be less than the thickness 134 (as illustrated in FIG. 2, with the source region 128-1 and the drain region 128-2 each disposed between some of the channel material 102 and the substrate 122), while in other embodiments, the thickness 132 may be equal to the thickness 136. The thickness 134 may have any values as discussed above with reference to the thickness 110 of the channel material 102.

In the embodiment of FIG. 2, the transistor S/D stack 104 is shown as disposed on a substrate 122. The substrate 122 may be any structure on which the transistor S/D stack 104, or other elements of the transistor 120, is disposed. In some embodiments, the substrate 122 may include a semiconductor, such as silicon. In some embodiments, the substrate 122 may include an insulating layer, such as an oxide isolation layer. For example, in the embodiments of FIGS. 2 and 3, the substrate 122 may include a semiconductor material and an interface layer dielectric (ILD) disposed between the semiconductor material and the source region 128-1, the channel material 102, and the drain region 128-2, to electrically isolate the semiconductor material of the substrate 122 from the S/D regions 128-1 and 128-2, and the channel material 102 (and thereby mitigate the likelihood that a conductive pathway will form between the source region 128-1 and the drain region 128-2 through the substrate 122) . Examples of ILDs that may be included in a substrate 122 in some embodiments may include silicon oxide, silicon nitride, aluminum oxide, and/or silicon oxynitride. Any suitable ones of the embodiments of the substrate 122 described with reference to FIG. 2 may be used for the substrates 122 of others of the transistors 120 disclosed herein.

The gate electrode material 124 may include at least one P-type work function metal or N-type work function metal, depending on whether the transistor 120 is a P-type metal oxide semiconductor (PMOS) transistor or an N-type metal oxide semiconductor (NMOS) transistor (P-type work function metal used as the gate electrode 124 when the transistors 120 is a PMOS transistor and N-type work function metal used as the gate electrode 124 when the transistor 120 is an NMOS transistor). For a PMOS transistor, metals that may be used for the gate electrode material 124 may include, but are not limited to, ruthenium, palladium, platinum, cobalt, nickel, and conductive metal oxides (e.g., ruthenium oxide). For an NMOS transistor, metals that may be used for the gate electrode material 124 include, but are not limited to, hafnium, zirconium, titanium, tantalum, aluminum, alloys of these metals, and carbides of these metals (e.g., hafnium carbide, zirconium carbide, titanium carbide, tantalum carbide, and aluminum carbide). In some embodiments, the gate electrode material 124 may consist of a stack of two or more metal layers, where one or more metal layers are work function metal layers and at least one metal layer is a fill metal layer. Further layers may be included next to the gate electrode material 124 for other purposes, such as to act as a diffusion barrier layer or/and an adhesion layer, not specifically shown in FIG. 2.

In some embodiments, the gate dielectric 126 may be a high-k dielectric (i.e. a dielectric material that has a higher dielectric constant (k) than silicon dioxide) including elements such as hafnium, silicon, oxygen, titanium, tantalum, lanthanum, aluminum, zirconium, barium, strontium, yttrium, lead, scandium, niobium, and zinc. Examples of high-k materials that may be used in the gate dielectric 126 may include, but are not limited to, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, tantalum oxide, tantalum silicon oxide, lead scandium tantalum oxide, and lead zinc niobate.

In some embodiments, an annealing process may be carried out on the gate dielectric 126 during manufacture of the transistor 120 to improve the quality of the gate dielectric 126. The gate dielectric 126 may have a thickness, a dimension measured in the vertical direction in the view of FIG. 2, that may, in some embodiments, be between 0.5 nanometers and 3 nanometers, including all values and ranges therein (e.g., between 1 and 3 nanometers, or between 1 and 2 nanometers).

In some embodiments, the gate dielectric 126 and the gate electrode 124 may be surrounded by a gate spacer, not shown in FIG. 1, configured to provide separation between the gates of different transistors and typically is made of a low-k dielectric material, such as e.g. any of the low-k dielectric materials described above with reference to the dielectric spacer 130.

FIG. 3 depicts a transistor 120 including a transistor S/D stack 104 and having a single “bottom” gate provided by the gate electrode material 124 and the gate dielectric 126.

If in the embodiment of FIG. 2, the amorphous interlayer arrangement 100 is shown as disposed on a substrate 122 in an orientation “upside down” to the one illustrated in FIG. 1; then in the embodiment of FIG. 3, the amorphous interlayer arrangement 100 is shown as disposed on a substrate 122 in the same orientation as the one illustrated in FIG. 1, i.e. the doped amorphous semiconductor material 106 is provided over the channel material 102 and the S/D electrode material 108 is provided over the doped amorphous semiconductor material 106.

Reference numerals used to label elements of FIG. 3 which are the same as reference numerals used to label elements of FIG. 2 and FIG. 1 are intended to illustrate similar or same elements and, therefore, discussions of these elements provided with respect to one of the figures are applicable to other figures. Therefore, these discussions are not repeated for FIG. 3.

FIGS. 4A and 4B are perspective and cross-sectional side views, respectively, of an example tri-gate transistor 120 including a transistor S/D stack 104, in accordance with various embodiments. In particular, FIG. 4B illustrates a cross-section of the transistor 120 of FIG. 4A taken along the section A-A of FIG. 4A (i.e. the x-z plane of the reference coordinate system shown in FIG. 4A).

The transistor 120 of FIGS. 4A and 4B may include one or more semiconductor materials, including a channel material 102, as described above, the one or more semiconductor materials formed as a fin 140 extending from a base which may be a substrate, e.g. the substrate 122 as described above. A gate stack including a gate electrode material 124 and a high-k dielectric 126 may wrap around the fin 140 as shown, with the active region of the channel material 102 corresponding to the portion of the fin 140 wrapped by the gate stack. In particular, the high-k dielectric 126 may wrap around the fin 140 and the gate electrode material 124 may wrap around the high-k dielectric 126.

As shown in FIG. 4A, the lower portion of the fin 140, i.e. the portion that is closest to the substrate 122, is enclosed by a dielectric material 142, typically an oxide, commonly referred to as a “shallow trench isolation” (STI). The dielectric material 142 may include any of the high-k dielectric materials described herein.

The fin 140 may include a source region 128-1 and a drain region 128-2 on either side of the gate stack, as shown. The composition of the channel material 102, the source region 128-1, and the drain region 128-2 may take the form of any of the embodiments disclosed herein, or known in the art. Although the fin 140 illustrated in FIGS. 4A and 4B is shown as having a rectangular cross section, the fin 140 may instead have a cross section that is rounded or sloped at the “top” of the fin 140, and the gate stack may conform to this rounded or sloped fin 140. In use, the tri-gate transistor 120 may form conducting channels on three “sides” of the fin 140 wrapped around by the gate stack, potentially improving performance relative to single-gate transistors (which may form conducting channels on one “side” of a channel material or substrate) and double-gate transistors (which may form conducting channels on two “sides” of a channel material or substrate).

The transistor source stack 104-1 and the transistor drain stack 104-2 are not explicitly illustrated in FIG. 4A but are shown in more detail in FIG. 4B. As shown in FIG. 4B, each of the transistor source stack 104-1 and the transistor drain stack 104-2 includes the S/D electrode material 108 and the doped amorphous semiconductor material 106 disposed between the S/D electrode material 108 and the channel material 102, as described above with reference to FIG. 1. As also shown in FIG. 4B, a dielectric spacer, such as the dielectric spacer 130 described above, may be provided between the transistor source stack 104-1 and the gate stack as well as between the transistor drain stack 104-2 and the gate stack in order to provide electrical isolation between the source, gate, drain electrodes.

FIGS. 5A and 5B are perspective and cross-sectional side views, respectively, of an example all-around gate transistor 120 including a transistor S/D stack 104, in accordance with various embodiments. Similar to FIG. 4B, FIG. 5B illustrates a cross-section of the transistor 120 of FIG. 5A taken along the section A-A of FIG. 5A (i.e. the x-z plane of the reference coordinate system shown in FIG. 5A).

The transistor 120 of FIGS. 5A and 5B may include one or more semiconductor materials, including a channel material 102, as described above, the one or more semiconductor materials formed as a wire 144 provided over a substrate, e.g. the substrate 122 as described above. The wire 144 may take the form of a nanowire or nanoribbon, for example. A gate stack including a gate electrode material 124 and a high-k dielectric 126 may wrap entirely or almost entirely around the wire 144 as shown, with the active region of the channel material 102 corresponding to the portion of the wire 144 wrapped by the gate stack. In particular, the high-k dielectric 126 may wrap around the wire 144 and the gate electrode material 124 may wrap around the high-k dielectric 126. In some embodiments, the gate stack may fully encircle the wire 144. In some embodiments, a layer of oxide material (not specifically shown in FIGS. 5A-5B) may be provided between the substrate 122 and the gate electrode 124.

The wire 144 may include a source region 128-1 and a drain region 128-2 on either side of the gate stack, as shown. The composition of the channel material 102, the source region 128-1, and the drain region 128-2 may take the form of any of the embodiments disclosed herein, or known in the art. Although the wire 144 illustrated in FIGS. 5A and 5B is shown as having a rectangular cross section, the wire 144 may instead have a cross section that is rounded or otherwise irregularly shaped, and the gate stack may conform to the shape of the wire 144. In use, the all-around-gate transistor 120 may form conducting channels on more than three “sides” of the wire 144, potentially improving performance relative to tri-gate transistors. Although FIGS. 5A and 5B depict an embodiment in which the longitudinal axis of the wire 144 runs substantially parallel to a plane of the substrate 122), this need not be the case; in other embodiments, for example, the wire 144 may be oriented “vertically” so as to be perpendicular to a plane of the substrate 122.

The transistor source stack 104-1 and the transistor drain stack 104-2 are not explicitly illustrated in FIG. 5A but are shown in more detail in FIG. 5B. As shown in FIG. 5B, each of the transistor source stack 104-1 and the transistor drain stack 104-2 includes the S/D electrode material 108 and the doped amorphous semiconductor material 106 disposed between the S/D electrode material 108 and the channel material 102, as described above with reference to FIG. 1. As also shown in FIG. 5B, a dielectric spacer, such as the dielectric spacer 130 described above, may be provided between the transistor source stack 104-1 and the gate stack as well as between the transistor drain stack 104-2 and the gate stack in order to provide electrical isolation between the source, gate, drain electrodes. FIG. 5B further illustrates that the

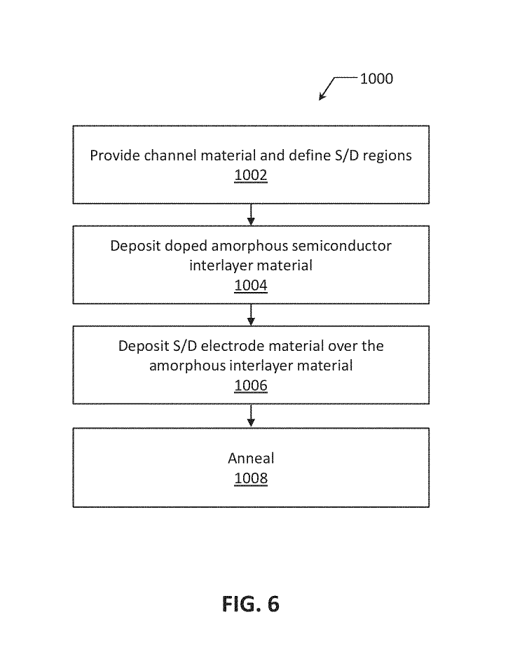

The transistor amorphous interlayer arrangements 100 having transistor S/D stacks 104 disclosed herein may be manufactured using any suitable techniques. For example, FIG. 6 is a flow diagram of an example method 1000 of manufacturing a transistor S/D stack, in accordance with various embodiments. Although the operations of the method 1000 are illustrated once each and in a particular order, the operations may be performed in any suitable order and repeated as desired. For example, one or more operations may be performed in parallel to manufacture multiple transistor S/D stacks substantially simultaneously. In another example, the operations may be performed in a different order to reflect the structure of a transistor in which the transistor S/D stack will be included.

At 1002, one or more semiconductor materials, including a semiconductor material for forming a channel, may be provided and future S/D regions may be defined within the one or more semiconductor materials. The one or more semiconductor materials provided at 1002 may take the form of any of the embodiments of the channel material 102 disclosed herein, for example (e.g., any of the embodiments discussed herein with reference to a transistor 120). The one or more semiconductor materials may be provided at 1002 using any suitable deposition and patterning technique known in the art. The S/D regions defined at 1002 may take the form of any of the embodiments of the S/D regions 128-1 and 128-2 disclosed herein, for example (e.g., any of the embodiments discussed herein with reference to a transistor 120).

At 1004, a thin amorphous interlayer may be provided over the semiconductor material of the S/D regions. The amorphous interlayer provided at 1004 may take the form of any of the embodiments of the doped amorphous semiconductor material 106 disclosed herein, for example. In some embodiments, the doped amorphous semiconductor material may be provided at 1004 so as to be in contact with the channel material of 1002. In other embodiments, an intermediate material may be disposed between the doped amorphous semiconductor material and the channel material. Doping to form a doped amorphous semiconductor material may be provided at 1004 in-situ (i.e. doping is performed during the deposition of the amorphous semiconductor material, in the same reaction chamber and without breaking the vacuum in the chamber as where the semiconductor material is deposited), using any suitable technique known in the art for depositing amorphous films, at temperatures that prevent crystallization of the doped amorphous semiconductor material. For example, in some embodiments, the layer of the doped amorphous semiconductor material may be provided at 1004 by physical vapor deposition (PVD), such as sputtering. In other embodiments, the layer of the doped amorphous semiconductor material may be provided at 1004 by atomic layer deposition (ALD) or by chemical vapor deposition (CVD).

In general, CVD or ALD is a chemical process in which one or more reactive precursor gases are introduced into a reaction chamber and directed towards a substrate in order to induce controlled chemical reactions that result in growth of a desired material on the substrate. The one or more reactive gases may be provided to the chamber at a flow rate of e.g. 5 standard cubic centimeter per minute (sccm) to 500 sccm, including all values and ranges therein. The reactive gas may be provided with a carrier gas, such as an inert gas, which may include, for example, argon. In some embodiments, the chamber may be maintained at a pressure in the range of 1 milliTorr to 100 milliTorr, including all values and ranges therein, and a temperature in the range of 100° C. to 500° C., including all values and ranges therein. The substrate itself may also be heated. In some embodiments, the process may be plasma assisted where electrodes are provided within the process chamber and are used to ionize the gases. Alternatively, plasma may be formed outside of the chamber and then supplied into the chamber. In the chamber, a layer of solid thin film material is deposited on the surface of the substrate due to reaction of the gas/gasses.

In process 1004, the substrate placed in the CVD or ALD reaction chamber may be a substrate including any suitable assembly on which the doped amorphous semiconductor interlayer in according with embodiments disclosed herein is to be deposited. For example, for a tri-gate transistor as e.g. illustrated in FIGS. 4A-4B, the substrate placed in the reaction chamber could be a substrate having the fin 140 formed thereon, where the sub-fin portion of the fin is enclosed by the STI 142. The substrate could also include the gate stack deposited over the fin, but no source/drain electrodes yet, as shown in FIG. 4A. The layer of solid thin film material is deposited on the surface of such a substrate due to reaction of precursor gasses in the reaction chamber is the layer of the doped amorphous semiconductor material as described herein. A selection of particular one or more precursor gases used in process 1004 would depend on which semiconductor material was selected to be deposited in process 1004 (e.g. germanium, silicon germanium, silicon, etc.) and which dopant is to be included in such a semiconductor material. For example, the doped amorphous semiconductor material may be deposited by CVD or ALD using a germanium precursor gas as a reactive precursor for forming a desired amorphous semiconductor (in this example—germanium) and a phosphine (PH3) dopant gas as a reactive precursor for including desired dopants (in this example—phosphorus) in the semiconductor material being deposited, to produce a layer of amorphous germanium doped with phosphorus. The concentration of dopants (i.e. phosphorus in this example) depends upon ratio of the semiconductor precursor and dopant precursor gases flown simultaneously inside the germanium growth chamber. Suitably adjusting the ratio of these two reactive precursor gasses can result in very high doping levels. Selecting appropriate semiconductor precursor and dopant precursor gasses allows depositing a large variety of amorphous semiconductor materials doped with desired dopants.

At 1006, the S/D electrode material may be provided. The S/D electrode material provided at 1006 may take the form of any of the embodiments of the S/D electrode material 108 disclosed herein, for example (e.g., any of the embodiments discussed herein with reference to a transistor 120). The S/D electrode material may be provided at 1006 using any suitable deposition and patterning technique known in the art.

At 1008, anneal is performed to activate the dopants of the doped amorphous semiconductor material provided at 1004. In some embodiments, such an anneal may involve heating the substrate on which the S/D stack is provided to temperatures between 100 and 400 degrees Celsius, for the time ranging from milliseconds to several minutes.

The method 1000 may further include other manufacturing operations related to fabrication of other components of a transistor 120. For example, the method 1000 may include providing a gate stack including a gate electrode and a gate dielectric, e.g., in accordance with any suitable ones of the embodiments discussed above. In some embodiments, the method 1000 may include providing doped source region and drain regions, e.g., in accordance with any suitable ones of the embodiments discussed above.

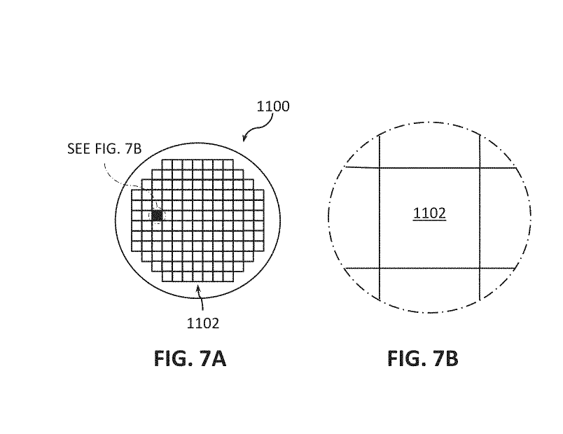

The transistor source/drain stacks disclosed herein may be included in any suitable electronic device. FIGS. 7-10 illustrate various examples of apparatuses that may include one or more of the transistor source/drain stacks disclosed herein.

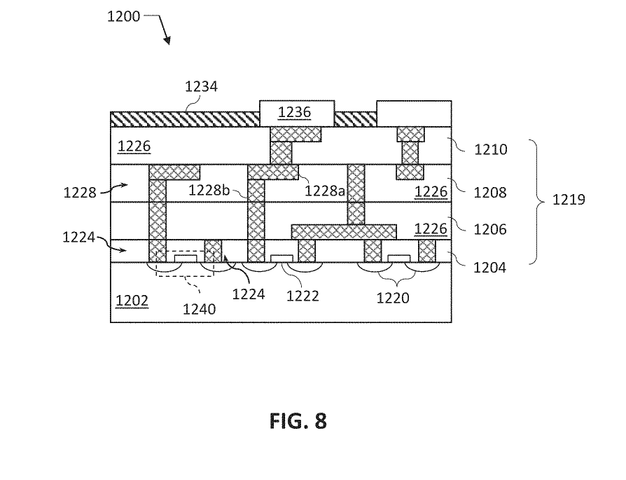

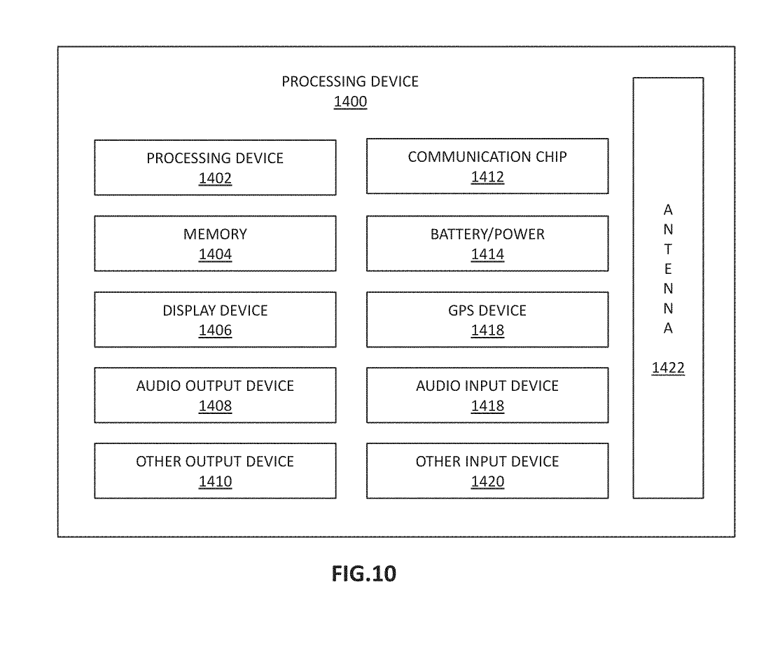

FIGS. 7A-B are top views of a wafer 1100 and dies 1102 that may include one or more transistor source/drain stacks in accordance with any of the embodiments disclosed herein. The wafer 1100 may be composed of semiconductor material and may include one or more dies 1102 having IC structures formed on a surface of the wafer 1100. Each of the dies 1102 may be a repeating unit of a semiconductor product that includes any suitable IC (e.g., ICs including one or more transistors 120 that include one or more transistor S/D stacks 104). After the fabrication of the semiconductor product is complete (e.g., after manufacture of a transistor S/D stack 104 in a transistor 120), the wafer 1100 may undergo a singulation process in which each of the dies 1102 is separated from one another to provide discrete “chips” of the semiconductor product. In particular, devices that include a transistor source/drain stack as disclosed herein may take the form of the wafer 1100 (e.g., not singulated) or the form of the die 1102 (e.g., singulated). The die 1102 may include one or more transistors (e.g., one or more of the transistors 1240 of FIG. 8, discussed below, which may take the form of any of the transistors 120) and/or supporting circuitry to route electrical signals to the transistors, as well as any other IC components. In some embodiments, the wafer 1100 or the die 1102 may include a memory device (e.g., a static random access memory (SRAM) device), a logic device (e.g., an AND, OR, NAND, or NOR gate), or any other suitable circuit element. Multiple ones of these devices may be combined on a single die 1102. For example, a memory array formed by multiple memory devices may be formed on a same die 1102 as a processing device (e.g., the processing device 1402 of FIG. 10) or other logic that is configured to store information in the memory devices or execute instructions stored in the memory array.

FIG. 8 is a cross-sectional side view of an IC device 1200 that may include one or more transistor source/drain stacks in accordance with any of the embodiments disclosed herein. The IC device 1200 may be formed on a substrate 1202 (e.g., the wafer 1100 of FIG. 7A) and may be included in a die (e.g., the die 1102 of FIG. 7B). The substrate 1202 may be a semiconductor substrate composed of semiconductor material systems including, for example, N-type or P-type materials systems. The substrate 1202 may include, for example, a crystalline substrate formed using a bulk silicon or a silicon-on-insulator substructure. In some embodiments, the semiconductor substrate 1202 may be formed using alternative materials, which may or may not be combined with silicon, that include, but are not limited to, germanium, indium antimonide, lead telluride, indium arsenide, indium phosphide, gallium arsenide, or gallium antimonide. Further materials classified as group II-VI, III-V, or IV may also be used to form the substrate 1202. Although a few examples of materials from which the substrate 1202 may be formed are described here, any material that may serve as a foundation for an IC device 1200 may be used. The substrate 1202 may be part of a singulated die (e.g., the dies 1102 of FIG. 7B) or a wafer (e.g., the wafer 1100 of FIG. 7A).

The IC device 1200 may include one or more device layers 1204 disposed on the substrate 1202. The device layer 1204 may include features of one or more transistors 1240 (e.g., metal oxide semiconductor field-effect transistors (MOSFETs)) formed on the substrate 1202. The device layer 1204 may include, for example, one or more source and/or drain (S/D) regions 1220, a gate 1222 to control current flow in the transistors 1240 between the S/D regions 1220, and one or more S/D contacts 1224 to route electrical signals to/from the S/D regions 1220. The S/D regions 1220 may include the source region 128-1 and the drain region 128-2. In embodiments in which a transistor 1240 includes one or more transistor S/D stacks 104, the S/D contacts 1224 may include the transistor electrode material 108, and a layer of a doped amorphous semiconductor material according to any of the embodiments of the doped amorphous semiconductor material 106 disclosed herein may be provided between the S/D contacts 1224 and the channel material of the substrate 1202. The transistors 1240 may include additional features not depicted for the sake of clarity, such as device isolation regions, gate contacts, and the like. The transistors 1240 are not limited to the type and configuration depicted in FIG. 8 and may include a wide variety of other types and configurations such as, for example, planar transistors, non-planar transistors, or a combination of both. Non-planar transistors may include FinFET transistors, such as double-gate transistors or tri-gate transistors, and wrap-around or all-around gate transistors, such as nanoribbon and nanowire transistors. In particular, one or more of the transistors 1240 may include one or more transistor S/D stacks 104 in accordance with any of the embodiments disclosed herein. For example, a transistor 1240 may take the form of any of the transistors 120 disclosed herein (e.g., any of the single-gate transistors discussed herein with reference to FIGS. 2-3, any of the double-gate transistors not specifically shown in present FIGS., any of the tri-gate transistors discussed herein with reference to FIGS. 4A and 4B, and any of the all-around-gate transistors discussed herein with reference to FIGS. 5A and 5B).

Each transistor 1240 may include a gate 1222 formed of at least two layers, a gate dielectric layer and a gate electrode layer. The gate electrode layer may take the form of any of the embodiments of the gate electrode material 124 disclosed herein. Generally, the gate dielectric layer of a transistor 1240 may include one layer or a stack of layers, and the one or more layers may include silicon oxide, silicon dioxide, and/or a high-k dielectric material. The high-k dielectric material included in the gate dielectric layer of the transistor 1240 may take the form of any of the embodiments of the high-k dielectric 126 disclosed herein, for example.

In some embodiments, when viewed as a cross section of the transistor 1240 along the source-channel-drain direction, the gate electrode may consist of a U-shaped structure that includes a bottom portion substantially parallel to the surface of the substrate and two sidewall portions that are substantially perpendicular to the top surface of the substrate (e.g., as discussed above with reference to the tri-gate transistor 120 of FIGS. 4A and 4B). In other embodiments, at least one of the metal layers that form the gate electrode may simply be a planar layer that is substantially parallel to the top surface of the substrate and does not include sidewall portions substantially perpendicular to the top surface of the substrate. In other embodiments, the gate electrode may consist of a combination of U-shaped structures and planar, non-U-shaped structures. For example, the gate electrode may consist of one or more U-shaped metal layers formed atop one or more planar, non-U-shaped layers. In some embodiments, the gate electrode may consist of a V-shaped structure (e.g., when the fin 140 does not have a “flat” upper surface, but instead has a rounded peak).

In some embodiments, a pair of sidewall spacers may be formed on opposing sides of the gate stack to bracket the gate stack. The sidewall spacers may be formed from a material such as silicon nitride, silicon oxide, silicon carbide, silicon nitride doped with carbon, and silicon oxynitride. Processes for forming sidewall spacers are well known in the art and generally include deposition and etching process steps. In some embodiments, a plurality of spacer pairs may be used; for instance, two pairs, three pairs, or four pairs of sidewall spacers may be formed on opposing sides of the gate stack.

The S/D regions 1220 may be formed within the substrate 1202 adjacent to the gate 1222 of each transistor 1240. The S/D regions 1220 may take the form of any of the embodiments of the source region 128-1 and the drain region 128-2 discussed above with reference to the transistors 120. In other embodiments, the S/D regions 1220 may be formed using any suitable processes known in the art. For example, the S/D regions 1220 may be formed using either an implantation/diffusion process or a deposition process. In the former process, dopants such as boron, aluminum, antimony, phosphorous, or arsenic may be ion-implanted into the substrate 1202 to form the S/D regions 1220. An annealing process that activates the dopants and causes them to diffuse farther into the substrate 1202 may follow the ion implantation process. In the latter process, an epitaxial deposition process may provide material that is used to fabricate the S/D regions 1220. In some implementations, the S/D regions 1220 may be fabricated using a silicon alloy such as silicon germanium or silicon carbide. In some embodiments, the epitaxially deposited silicon alloy may be doped in situ with dopants such as boron, arsenic, or phosphorous. In some embodiments, the S/D regions 1220 may be formed using one or more alternate semiconductor materials such as germanium or a group III-V material or alloy. In further embodiments, one or more layers of metal and/or metal alloys may be used to form the S/D regions 1220 (e.g., as discussed above with reference to the source region 128-1 and the drain region 128-2). In some embodiments, an etch process may be performed before the epitaxial deposition to create recesses in the substrate 1202 in which the material for the S/D regions 1220 is deposited.

Electrical signals, such as power and/or input/output (I/O) signals, may be routed to and/or from the transistors 1240 of the device layer 1204 through one or more interconnect layers disposed on the device layer 1204 (illustrated in FIG. 8 as interconnect layers 1206-1210). For example, electrically conductive features of the device layer 1204 (e.g., the gate 1222 and the S/D contacts 1224) may be electrically coupled with the interconnect structures 1228 of the interconnect layers 1206-1210. The one or more interconnect layers 1206-1410 may form an interlayer dielectric (ILD) stack 1219 of the IC device 1200.

The interconnect structures 1228 may be arranged within the interconnect layers 1206-1210 to route electrical signals according to a wide variety of designs (in particular, the arrangement is not limited to the particular configuration of interconnect structures 1228 depicted in FIG. 8). Although a particular number of interconnect layers 1206-1210 is depicted in FIG. 8, embodiments of the present disclosure include IC devices having more or fewer interconnect layers than depicted.

In some embodiments, the interconnect structures 1228 may include trench structures 1228a (sometimes referred to as “lines”) and/or via structures 1228b (sometimes referred to as “holes”) filled with an electrically conductive material such as a metal. The trench structures 1228a may be arranged to route electrical signals in a direction of a plane that is substantially parallel with a surface of the substrate 1202 upon which the device layer 1204 is formed. For example, the trench structures 1228a may route electrical signals in a direction in and out of the page from the perspective of FIG. 8. The via structures 1228b may be arranged to route electrical signals in a direction of a plane that is substantially perpendicular to the surface of the substrate 1202 upon which the device layer 1204 is formed. In some embodiments, the via structures 1228b may electrically couple trench structures 1228a of different interconnect layers 1206-1210 together.

The interconnect layers 1206-1210 may include a dielectric material 1226 disposed between the interconnect structures 1228, as shown in FIG. 8. In some embodiments, the dielectric material 1226 disposed between the interconnect structures 1228 in different ones of the interconnect layers 1206-1210 may have different compositions; in other embodiments, the composition of the dielectric material 1226 between different interconnect layers 1206-1210 may be the same.

A first interconnect layer 1206 (referred to as Metal 1 or “M1”) may be formed directly on the device layer 1204. In some embodiments, the first interconnect layer 1206 may include trench structures 1228a and/or via structures 1228b, as shown. The trench structures 1228a of the first interconnect layer 1206 may be coupled with contacts (e.g., the S/D contacts 1224) of the device layer 1204.

A second interconnect layer 1208 (referred to as Metal 2 or “M2”) may be formed directly on the first interconnect layer 1206. In some embodiments, the second interconnect layer 1208 may include via structures 1228b to couple the trench structures 1228a of the second interconnect layer 1208 with the trench structures 1228a of the first interconnect layer 1206. Although the trench structures 1228a and the via structures 1228b are structurally delineated with a line within each interconnect layer (e.g., within the second interconnect layer 1208) for the sake of clarity, the trench structures 1228a and the via structures 1228b may be structurally and/or materially contiguous (e.g., simultaneously filled during a dual-damascene process) in some embodiments.

A third interconnect layer 1210 (referred to as Metal 3 or “M3”) (and additional interconnect layers, as desired) may be formed in succession on the second interconnect layer 1208 according to similar techniques and configurations described in connection with the second interconnect layer 1208 or the first interconnect layer 1206.

The IC device 1200 may include a solder resist material 1234 (e.g., polyimide or similar material) and one or more bond pads 1236 formed on the interconnect layers 1206-1210. The bond pads 1236 may be electrically coupled with the interconnect structures 1228 and configured to route the electrical signals of the transistor(s) 1240 to other external devices. For example, solder bonds may be formed on the one or more bond pads 1236 to mechanically and/or electrically couple a chip including the IC device 1200 with another component (e.g., a circuit board). The IC device 1200 may have other alternative configurations to route the electrical signals from the interconnect layers 1206-1210 than depicted in other embodiments. For example, the bond pads 1236 may be replaced by or may further include other analogous features (e.g., posts) that route the electrical signals to external components.

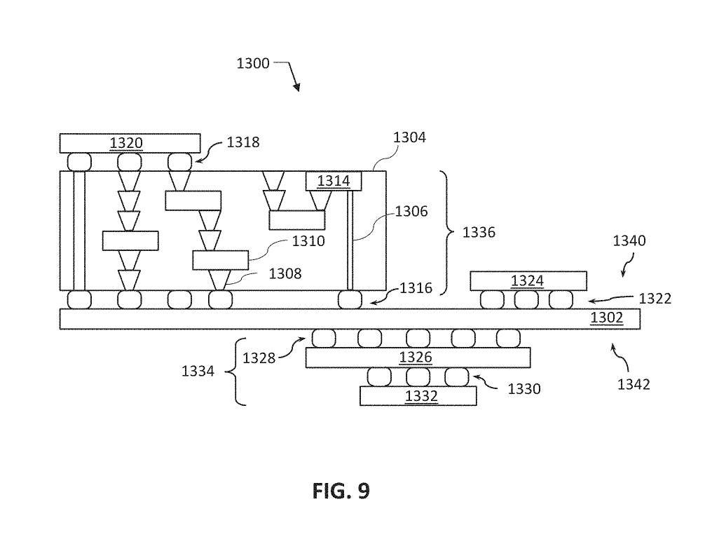

FIG. 9 is a cross-sectional side view of an IC device assembly 1300 that may include components having one or more transistor source/drain stacks in accordance with any of the embodiments disclosed herein. The IC device assembly 1300 includes a number of components disposed on a circuit board 1302 (which may be, e.g., a motherboard). The IC device assembly 1300 includes components disposed on a first face 1340 of the circuit board 1302 and an opposing second face 1342 of the circuit board 1302; generally, components may be disposed on one or both faces 1340 and 1342. In particular, any suitable ones of the components of the IC device assembly 1300 may include any of the transistor S/D stacks 104 disclosed herein (e.g., in any of the transistors 120 disclosed herein).

In some embodiments, the circuit board 1302 may be a printed circuit board (PCB) including multiple metal layers separated from one another by layers of dielectric material and interconnected by electrically conductive vias. Any one or more of the metal layers may be formed in a desired circuit pattern to route electrical signals (optionally in conjunction with other metal layers) between the components coupled to the circuit board 1302. In other embodiments, the circuit board 1302 may be a non-PCB substrate.

The IC device assembly 1300 illustrated in FIG. 9 includes a package-on-interposer structure 1336 coupled to the first face 1340 of the circuit board 1302 by coupling components 1316. The coupling components 1316 may electrically and mechanically couple the package-on-interposer structure 1336 to the circuit board 1302, and may include solder balls (as shown in FIG. 9), male and female portions of a socket, an adhesive, an underfill material, and/or any other suitable electrical and/or mechanical coupling structure.

The package-on-interposer structure 1336 may include an IC package 1320 coupled to an interposer 1304 by coupling components 1318. The coupling components 1318 may take any suitable form for the application, such as the forms discussed above with reference to the coupling components 1316. Although a single IC package 1320 is shown in FIG. 9, multiple IC packages may be coupled to the interposer 1304; indeed, additional interposers may be coupled to the interposer 1304. The interposer 1304 may provide an intervening substrate used to bridge the circuit board 1302 and the IC package 1320. The IC package 1320 may be or include, for example, a die (the die 1102 of FIG. 7B), an IC device (e.g., the IC device 1200 of FIG. 8), or any other suitable component. Generally, the interposer 1304 may spread a connection to a wider pitch or reroute a connection to a different connection. For example, the interposer 1304 may couple the IC package 1320 (e.g., a die) to a ball grid array (BGA) of the coupling components 1316 for coupling to the circuit board 1302. In the embodiment illustrated in FIG. 9, the IC package 1320 and the circuit board 1302 are attached to opposing sides of the interposer 1304; in other embodiments, the IC package 1320 and the circuit board 1302 may be attached to a same side of the interposer 1304. In some embodiments, three or more components may be interconnected by way of the interposer 1304.

The interposer 1304 may be formed of an epoxy resin, a fiberglass-reinforced epoxy resin, a ceramic material, or a polymer material such as polyimide. In some implementations, the interposer 1304 may be formed of alternate rigid or flexible materials that may include the same materials described above for use in a semiconductor substrate, such as silicon, germanium, and other group III-V and group IV materials. The interposer 1304 may include metal interconnects 1308 and vias 1310, including but not limited to through-silicon vias (TSVs) 1306. The interposer 1304 may further include embedded devices 1314, including both passive and active devices. Such devices may include, but are not limited to, capacitors, decoupling capacitors, resistors, inductors, fuses, diodes, transformers, sensors, electrostatic discharge (ESD) devices, and memory devices. More complex devices such as radio-frequency (RF) devices, power amplifiers, power management devices, antennas, arrays, sensors, and microelectromechanical systems (MEMS) devices may also be formed on the interposer 1304. The package-on-interposer structure 1336 may take the form of any of the package-on-interposer structures known in the art.

The IC device assembly 1300 may include an IC package 1324 coupled to the first face 1340 of the circuit board 1302 by coupling components 1322. The coupling components 1322 may take the form of any of the embodiments discussed above with reference to the coupling components 1316, and the IC package 1324 may take the form of any of the embodiments discussed above with reference to the IC package 1320.

The IC device assembly 1300 illustrated in FIG. 9 includes a package-on-package structure 1334 coupled to the second face 1342 of the circuit board 1302 by coupling components 1328. The package-on-package structure 1334 may include an IC package 1326 and an IC package 1332 coupled together by coupling components 1330 such that the IC package 1326 is disposed between the circuit board 1302 and the IC package 1332. The coupling components 1328 and 1330 may take the form of any of the embodiments of the coupling components 1316 discussed above, and the IC packages 1326 and 1332 may take the form of any of the embodiments of the IC package 1320 discussed above. The package-on-package structure 1334 may be configured in accordance with any of the package-on-package structures known in the art.

FIG. 10 is a block diagram of an example computing device 1400 that may include one or more components including one or more transistor source/drain stacks in accordance with any of the embodiments disclosed herein. For example, any suitable ones of the components of the computing device 1400 may include a die (e.g., the die 1102 (FIG. 7B)) having one or more transistors 120 including one or more transistor S/D stacks 104. Any one or more of the components of the computing device 1400 may include, or be included in, an IC device 1200 (FIG. 8). Any one or more of the components of the computing device 1400 may include, or be included in, an IC device assembly 1300 (FIG. 9).

A number of components are illustrated in FIG. 10 as included in the computing device 1400, but any one or more of these components may be omitted or duplicated, as suitable for the application. In some embodiments, some or all of the components included in the computing device 1400 may be attached to one or more motherboards. In some embodiments, some or all of these components are fabricated onto a single system-on-a-chip (SoC) die.

Additionally, in various embodiments, the computing device 1400 may not include one or more of the components illustrated in FIG. 10, but the computing device 1400 may include interface circuitry for coupling to the one or more components. For example, the computing device 1400 may not include a display device 1406, but may include display device interface circuitry (e.g., a connector and driver circuitry) to which a display device 1406 may be coupled. In another set of examples, the computing device 1400 may not include an audio input device 1424 or an audio output device 1408, but may include audio input or output device interface circuitry (e.g., connectors and supporting circuitry) to which an audio input device 1424 or audio output device 1408 may be coupled.

The computing device 1400 may include a processing device 1402 (e.g., one or more processing devices). As used herein, the term “processing device” or “processor” may refer to any device or portion of a device that processes electronic data from registers and/or memory to transform that electronic data into other electronic data that may be stored in registers and/or memory. The processing device 1402 may include one or more digital signal processors (DSPs), application-specific integrated circuits (ASICs), central processing units (CPUs), graphics processing units (GPUs), cryptoprocessors (specialized processors that execute cryptographic algorithms within hardware), server processors, or any other suitable processing devices. The computing device 1400 may include a memory 1404, which may itself include one or more memory devices such as volatile memory (e.g., dynamic random access memory (DRAM)), nonvolatile memory (e.g., read-only memory (ROM)), flash memory, solid state memory, and/or a hard drive. In some embodiments, the memory 1404 may include memory that shares a die with the processing device 1402. This memory may be used as cache memory and may include embedded dynamic random access memory (eDRAM) or spin transfer torque magnetic random-access memory (STT-MRAM).

In some embodiments, the computing device 1400 may include a communication chip 1412 (e.g., one or more communication chips). For example, the communication chip 1412 may be configured for managing wireless communications for the transfer of data to and from the computing device 1400. The term “wireless” and its derivatives may be used to describe circuits, devices, systems, methods, techniques, communications channels, etc., that may communicate data through the use of modulated electromagnetic radiation through a nonsolid medium. The term does not imply that the associated devices do not contain any wires, although in some embodiments they might not.

The communication chip 1412 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultramobile broadband (UMB) project (also referred to as “3GPP2”), etc.). IEEE 802.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 802.16 standards. The communication chip 1412 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. The communication chip 1412 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication chip 1412 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. The communication chip 1412 may operate in accordance with other wireless protocols in other embodiments. The computing device 1400 may include an antenna 1422 to facilitate wireless communications and/or to receive other wireless communications (such as AM or FM radio transmissions).

In some embodiments, the communication chip 1412 may manage wired communications, such as electrical, optical, or any other suitable communication protocols (e.g., the Ethernet). As noted above, the communication chip 1412 may include multiple communication chips. For instance, a first communication chip 1412 may be dedicated to shorter-range wireless communications such as Wi-Fi or Bluetooth, and a second communication chip 1412 may be dedicated to longer-range wireless communications such as GPS, EDGE, GPRS, CDMA, WiMAX, LTE, EV-DO, or others. In some embodiments, a first communication chip 1412 may be dedicated to wireless communications, and a second communication chip 1412 may be dedicated to wired communications.

The computing device 1400 may include battery/power circuitry 1414. The battery/power circuitry 1414 may include one or more energy storage devices (e.g., batteries or capacitors) and/or circuitry for coupling components of the computing device 1400 to an energy source separate from the computing device 1400 (e.g., AC line power).

The computing device 1400 may include a display device 1406 (or corresponding interface circuitry, as discussed above). The display device 1406 may include any visual indicators, such as a heads-up display, a computer monitor, a projector, a touchscreen display, a liquid crystal display (LCD), a light-emitting diode display, or a flat panel display, for example.

The computing device 1400 may include an audio output device 1408 (or corresponding interface circuitry, as discussed above). The audio output device 1408 may include any device that generates an audible indicator, such as speakers, headsets, or earbuds, for example.

The computing device 1400 may include an audio input device 1424 (or corresponding interface circuitry, as discussed above). The audio input device 1424 may include any device that generates a signal representative of a sound, such as microphones, microphone arrays, or digital instruments (e.g., instruments having a musical instrument digital interface (MIDI) output).

The computing device 1400 may include a global positioning system (GPS) device 1418 (or corresponding interface circuitry, as discussed above). The GPS device 1418 may be in communication with a satellite-based system and may receive a location of the computing device 1400, as known in the art.

The computing device 1400 may include another output device 1410 (or corresponding interface circuitry, as discussed above). Examples of the other output device 1410 may include an audio codec, a video codec, a printer, a wired or wireless transmitter for providing information to other devices, or an additional storage device.

The computing device 1400 may include another input device 1420 (or corresponding interface circuitry, as discussed above). Examples of the other input device 1420 may include an accelerometer, a gyroscope, a compass, an image capture device, a keyboard, a cursor control device such as a mouse, a stylus, a touchpad, a bar code reader, a Quick Response (QR) code reader, any sensor, or a radio frequency identification (RFID) reader.

The computing device 1400 may have any desired form factor, such as a hand-held or mobile computing device (e.g., a cell phone, a smart phone, a mobile internet device, a music player, a tablet computer, a laptop computer, a netbook computer, an ultrabook computer, a personal digital assistant (PDA), an ultramobile personal computer, etc.), a desktop computing device, a server or other networked computing component, a printer, a scanner, a monitor, a set-top box, an entertainment control unit, a vehicle control unit, a digital camera, a digital video recorder, or a wearable computing device. In some embodiments, the computing device 1400 may be any other electronic device that processes data.

The following paragraphs provide various examples of the embodiments disclosed herein.

Example 1 provides a transistor amorphous interlayer arrangement, including a channel material forming a channel of a transistor, the channel material being e.g. germanium, and a transistor source/drain stack. The transistor source/drain stack includes a transistor electrode material configured to be a transistor S/D contact, i.e. either a source contact or a drain contact of the transistor, and a doped amorphous semiconductor material disposed between the transistor electrode material and the channel material.

Example 2 provides the transistor amorphous interlayer arrangement according to Example 1, where the doped amorphous semiconductor material has a doping concentration between 1·10²⁰ dopant elements per cubic centimeter and 3·10²⁰ dopant elements per cubic centimeter.

Example 3 provides the transistor amorphous interlayer arrangement according to Examples 1 or 2, where the doped amorphous semiconductor material has a thickness between 1 nanometers and 5 nanometers.

Example 4 provides the transistor amorphous interlayer arrangement according to any one of the preceding Examples, where the doped amorphous semiconductor material includes germanium, silicon germanium, or silicon.

Example 5 provides the transistor amorphous interlayer arrangement according to any one of the preceding Examples, where the transistor source/drain stack further includes a source/drain region and where the source/drain region includes a doped crystalline channel material, the doped crystalline channel material including the channel material doped with a doping concentration between 1·10²⁰ dopant elements per cubic centimeter and 1·10²¹ dopant elements per cubic centimeter, and the doped amorphous semiconductor material is in contact with the doped crystalline channel material.

Example 6 provides the transistor amorphous interlayer arrangement according to any one of the preceding Examples, where the doped amorphous semiconductor material is in contact with the channel material. Thus, in some embodiments, the source/drain regions including a highly doped crystalline material of the channel material, as used in conventional transistors, may be eliminated altogether. Such embodiments may advantageously achieve reducing the amount of defects formed by attempting to dope germanium channel, thus improving the overall performance of the transistor.

Example 7 provides the transistor amorphous interlayer arrangement according to any one of the preceding Examples, where the doped amorphous semiconductor material is in contact with the transistor electrode material.

Example 8 provides the transistor amorphous interlayer arrangement according to any one of the preceding Examples, where the transistor electrode material has a thickness between 1 nanometers and 10 nanometers.

Example 9 provides a transistor, including a channel material, the channel material including germanium; a gate electrode material; a source electrode material; a drain electrode material; and a doped amorphous semiconductor material disposed between the source electrode material and the channel material and disposed between the drain electrode material and the channel material.

Example 10 provides the transistor according to Example 9, where the transistor has a gate length between 20 and 30 nanometers.

Example 11 provides the transistor according to Example 9, where the channel material is coplanar with the source region and the drain region.

Example 12 provides the transistor according to Example 9, where the channel material is shaped as a fin extending away from a substrate over which the transistor is provided, the doped amorphous semiconductor material is disposed over a portion of a surface, or a side, of the fin that is opposite a surface of the fin closest to the substrate, and the gate electrode wraps around the fin.

Example 13 provides the transistor according to Example 9, where the channel material is shaped as a wire provided over a substrate over which the transistor is provided, the doped amorphous semiconductor material is disposed over a portion of a surface of the wire opposite a surface of the wire closest to the substrate, and the gate electrode wraps around the wire.

Example 14 provides the transistor according to any one of Examples 10-13, where the doped amorphous semiconductor material has a doping concentration between 1·10²⁰ dopant elements per cubic centimeter and 3·10²⁰ dopant elements per cubic centimeter.

Example 15 provides a computing device that includes a substrate; and an integrated circuit (IC) die coupled to the substrate. The IC die includes a transistor having a channel material, the channel material including germanium, a gate electrode material; a source electrode material; a drain electrode material; and a doped amorphous semiconductor material disposed between the source electrode material and the channel material and disposed between the drain electrode material and the channel material. Example 16 provides the computing device according to Example 15, where the computing device is a wearable or handheld computing device. Example 17 provides the computing device of any according to Examples 15 or 16, where the computing device further includes one or more communication chips and an antenna. Example 18 provides the computing device according to any one of Examples 15-17, where the substrate is a motherboard.

Example 19 provides a method of manufacturing a transistor. The method includes providing a channel material; depositing a layer of a doped amorphous semiconductor material over the channel material; and providing a transistor electrode material over the doped amorphous semiconductor material, where the transistor electrode material is either a source electrode material or a drain electrode material.

Example 20 provides the method according to Example 19, where depositing the layer of the doped amorphous semiconductor material includes performing in-situ deposition of the doped amorphous semiconductor material.

Example 21 provides the method according to Examples 19 or 20, where depositing the layer of the doped amorphous semiconductor material includes performing chemical vapor deposition (CVD) or atomic layer deposition (ALD) using a germanium precursor gas and a phosphine (PH3) dopant gas. In other embodiments, physical vapor deposition may be used to deposit the doped amorphous semiconductor material.

Example 22 provides the method according to Examples 19 or 20, where depositing the layer of the doped amorphous semiconductor material includes depositing amorphous germanium, silicon germanium, or silicon doped with donor-type dopants.

Example 23 provides the method according to any one of Examples 19-22, where the deposition is performed at temperatures that prevent crystallization of the doped amorphous semiconductor material.

Example 24 provides the method according to any one of Examples 19-23, further including performing an anneal of the transistor to activate dopants of the doped amorphous semiconductor material.

Example 25 provides the method according to any one of Examples 19-24, where providing the transistor electrode material includes depositing titanium, aluminum, titanium nitride, erbium, gadolinium, or ytterbium over the layer of the doped amorphous semiconductor material.

The above description of illustrated implementations of the disclosure, including what is described in the Abstract, is not intended to be exhaustive or to limit the disclosure to the precise forms disclosed. While specific implementations of, and examples for, the disclosure are described herein for illustrative purposes, various equivalent modifications are possible within the scope of the disclosure, as those skilled in the relevant art will recognize.

These modifications may be made to the disclosure in light of the above detailed description. The terms used in the following claims should not be construed to limit the disclosure to the specific implementations disclosed in the specification and the claims. Rather, the scope of the disclosure is to be determined entirely by the following claims, which are to be construed in accordance with established doctrines of claim interpretation.

1. A transistor amorphous interlayer arrangement, comprising:
a semiconductor material forming a channel of a transistor, the semiconductor material comprising germanium; and
a transistor source/drain stack, including:
a transistor electrode material configured to be either a source contact or a drain contact of the transistor, and
a doped amorphous semiconductor material disposed between the transistor electrode material and the semiconductor material.

2. The transistor amorphous interlayer arrangement according to claim 1, wherein the doped amorphous semiconductor material has a doping concentration between 1·10²⁰ dopant elements per cubic centimeter and 3·10²⁰ dopant elements per cubic centimeter.

3. The transistor amorphous interlayer arrangement according to claim 1, wherein the doped amorphous semiconductor material has a thickness between 1 nanometers and 5 nanometers.

4. The transistor amorphous interlayer arrangement according to claim 1, wherein the doped amorphous semiconductor material includes germanium, silicon germanium, or silicon.

5. The transistor amorphous interlayer arrangement according to claim 1, wherein the transistor source/drain stack further comprises a source/drain region and wherein the source/drain region comprises a doped crystalline semiconductor material, the doped crystalline semiconductor material comprising the semiconductor material doped with a doping concentration between 1·10²⁰ dopant elements per cubic centimeter and 1·10²¹ dopant elements per cubic centimeter, and the doped amorphous semiconductor material is in contact with the doped crystalline semiconductor material.

6. The transistor amorphous interlayer arrangement according to claim 1, wherein the doped amorphous semiconductor material is in contact with the semiconductor material.

7. The transistor amorphous interlayer arrangement according to claim 1, wherein the doped amorphous semiconductor material is in contact with the transistor electrode material.

8. The transistor amorphous interlayer arrangement according to claim 1, wherein the transistor electrode material has a thickness between 1 nanometers and 10 nanometers.

9. A transistor, comprising:
a semiconductor material forming a channel of the transistor, the semiconductor material comprising germanium;
a gate electrode material;
a source electrode material;
a drain electrode material; and
a doped amorphous semiconductor material disposed between the source electrode material and the semiconductor material and disposed between the drain electrode material and the semiconductor material.

10. The transistor according to claim 9, wherein the transistor has a gate length between 20 and 30 nanometers.

11. The transistor according to claim 9, wherein the semiconductor material is coplanar with the source region and the drain region.

12. The transistor according to claim 9, wherein the semiconductor material is shaped as a fin extending away from a substrate, the doped amorphous semiconductor material is disposed over a surface of the fin that is opposite a surface of the fin closest to the substrate, and the gate electrode wraps around the fin.

13. The transistor according to claim 9, wherein the semiconductor material is shaped as a wire provided over a substrate, the doped amorphous semiconductor material is disposed over a surface of the wire opposite a surface of the wire closest to the substrate, and the gate electrode wraps around the wire.

14. The transistor according to claim 10, wherein the doped amorphous semiconductor material has a doping concentration between 1·10²⁰ dopant elements per cubic centimeter and 3·10²⁰ dopant elements per cubic centimeter.

15-18. (canceled)

19. A method of manufacturing a transistor, comprising:
providing a semiconductor material for forming a channel of the transistor;
depositing a layer of a doped amorphous semiconductor material over the semiconductor material; and
providing a transistor electrode material over the doped amorphous semiconductor material, wherein the transistor electrode material is either a source electrode material or a drain electrode material.

20. The method according to claim 19, wherein depositing the layer of the doped amorphous semiconductor material comprises performing in-situ deposition of the doped amorphous semiconductor material.

21. The method according to claim 19, wherein depositing the layer of the doped amorphous semiconductor material comprises performing chemical vapor deposition (CVD) or atomic layer deposition (ALD) using a germanium precursor gas and a phosphine (PH3) dopant gas.

22. The method according to claim 19, wherein depositing the layer of the doped amorphous semiconductor material comprises depositing amorphous germanium, silicon germanium, or silicon doped with donor-type dopants.

23. (canceled)

24. The method according to claim 19, further comprising performing an anneal of the transistor to activate dopants of the doped amorphous semiconductor material.

25. The method according to claim 19, wherein providing the transistor electrode material comprises depositing titanium, aluminum, titanium nitride, erbium, gadolinium, or ytterbium over the layer of the doped amorphous semiconductor material.
